(19) United States
(12) Patent Application Publication
(10) Pub. No.: US 2015/0325695 A1
(43) Pub. Date: Nov. 12, 2015

(54) SEMICONDUCTOR APPARATUS, METHOD FOR FABRICATING THE SAME, AND VARIABLE RESISTIVE MEMORY DEVICE

(71) Applicant: SK hynix Inc., Gyeonggi-do (KR)

(72) Inventors: Jun Kyo SUH, Gyeonggi-do (KR); Kang Sik CHOI, Gyeonggi-do (KR)

(21) Appl. No.: 14/329,555

(22) Filed: Jul. 11, 2014

(30) Foreign Application Priority Data
May 9, 2014 (KR) 10-2014-0055709

(51) Int. Cl. H01L 29/78; H01L 29/66; H01L 27/24

(52) U.S. Cl. CPC H01L 29/7827; H01L 27/2454; H01L 29/66666; H01L 29/66553

(57) ABSTRACT

A semiconductor apparatus that includes a semiconductor substrate and a plurality of pillars formed in the semiconductor substrate. Each of the plurality of pillars includes a first pillar, and a second pillar formed on the first pillar, wherein the second pillar has a smaller linewidth than the first pillar.

### CROSS-REFERENCES TO RELATED APPLICATION

This application claims priority under 35 U.S.C. 119(a) to Korean application No. 10-2014-0055709, filed on May 9, 2014, in the Korean intellectual property Office, which is incorporated by reference in its entirety as set forth in full.

### BACKGROUND

1. Technical Field

Various embodiments of the inventive concept relate to a semiconductor apparatus having a vertical channel, a method for fabricating the same, and a variable resistive memory device.

2. Related Art

A transistor, which is a typical element in a semiconductor device, includes a gate, a source, and a drain. Transistors having two-dimensional (2D) structures may include a gate formed on a semiconductor substrate and a source and drain formed by doping the semiconductor substrate with impurities at both sides of the gate. The region between the source and the drain becomes the channel region of the transistor. As the transistor has a horizontal channel region defined by the linewidth of the gate, the ability to reduce the channel length below a certain linewidth is limited. Even when the channel length is capable of being reduced, phenomena occur that limit the ability of the transistor to function properly.

To overcome these limitations, vertical channel semiconductor devices have been used. The vertical channel semiconductor devices have an active region in a pillar form and a source and drain located in lower and upper portions of the pillar to form the vertical channel region.

In vertical channel semiconductor devices, a gate is extended in a line surrounding the pillar or in contact with either side of the pillar.

However, as the above-described vertical channel semiconductor devices are scaled down, the linewidth of the channel region is reduced, and the ON current is reduced. Therefore, there is a demand for new structure capable of increasing the ON current in these semiconductor devices.

### SUMMARY

An embodiment of the present invention is a semiconductor apparatus. The semiconductor apparatus may include a semiconductor substrate and a plurality of pillars formed in the semiconductor substrate. Each of the plurality of pillars may include a first pillar, and a second pillar formed on the first pillar, and having a smaller linewidth than the first pillar.

A second embodiment of the present invention is a method for fabricating a semiconductor apparatus. The method may include forming an upper pillar by first-etching a semiconductor substrate, forming a spacer on an outer wall of the upper pillar, and forming a lower pillar by second-etching the semiconductor substrate using the upper pillar and the spacer.

A third embodiment of the present invention is a variable resistive memory device. The variable resistive memory device may include a semiconductor substrate, a plurality of pillars formed in the semiconductor substrate, each of the pillars having two or more layers, wherein a first layer has a larger linewidth than a second layer formed on the first layer, among the two or more layers, a gate electrode formed to surround a lower region of each of the pillars, a source formed in the semiconductor substrate below the each of the pillars, a drain formed in an upper region of each of the pillars, and a variable resistance layer electrically coupled to the drain.

These and other features, aspects, and embodiments are described below in the section entitled “DETAILED DESCRIPTION”.

### BRIEF DESCRIPTION OF THE DRAWINGS

The above and other aspects, features and advantages of the subject matter of the present disclosure will be more clearly understood from the following detailed description taken in conjunction with the accompanying drawings, in which:

FIG. 1 is a cross-sectional view illustrating a semiconductor apparatus according to an embodiment of the inventive concept;

FIGS. 2 to 16 are cross-sectional views illustrating a method for fabricating a semiconductor apparatus according to an embodiment of the inventive concept;

FIG. 17 is a perspective view schematically illustrating a variable resistive memory device according to an embodiment of the inventive concept; and

FIG. 18 is a perspective view schematically illustrating a variable resistive memory device according to another embodiment of the inventive concept.

### DETAILED DESCRIPTION

Exemplary embodiments will be described in greater detail with reference to the accompanying drawings. Exemplary embodiments are described herein with reference to cross-sectional illustrations that are schematic illustrations of exemplary embodiments (and intermediate structures). As such, variations from the shapes of the illustrations as a result, for example, of manufacturing techniques and/or tolerances, are to be expected. Thus, embodiments should not be construed as limited to the particular shapes of regions illustrated herein but may include deviations in shapes that result, for example, from manufacturing. In the drawings, lengths and sizes of layers and regions may be exaggerated for clarity. Like reference numerals in the drawings denote like elements. It is also understood that when a layer is referred to as being “on” another layer or substrate, it can be directly on the other or substrate, or intervening layers may also be present. It is also noted that in this specification, “connected/coupled” refers to one component not only directly coupling another component but also indirectly coupling another component through an intermediate component. In addition, a singular form may include a plural form, and vice versa, as long as it is not specifically mentioned.

The inventive concept is described herein with reference to cross-section and/or plan illustrations that are schematic illustrations of idealized embodiments of the inventive concept. However, embodiments of the inventive concept should not be limited construed as limited to the inventive concept. Although a few embodiments of the inventive concept will be shown and described, it will be appreciated by those of ordinary skill in the art that changes may be made in these exemplary embodiments without departing from the principles and spirit of the inventive concept.

FIG. 1 is a cross-sectional view illustrating a semiconductor apparatus according to an embodiment of the inventive concept. Referring to FIG. 1, the semiconductor apparatus may include a semiconductor substrate 10 having a plurality of pillars 15, a gate electrode 80a surrounding a lower portion of each pillar 15, and an ohmic contact layer 130 surrounding an upper portion of the pillar 15.

The pillar 15 may include a first pillar 15b, and a second pillar 15a integrated with the first pillar 15b.

The first pillar 15b may correspond to a lower portion of the pillar 15 formed in the semiconductor substrate 10. The first pillar 15b may be formed to have a larger linewidth than the second pillar 15a to increase the ON current. In the embodiment, the first pillar 15b may also have a mesa structure in which its linewidth is gradually increased towards the bottom. In other words, the first pillar 15b may have a tapered sidewall from the bottom, i.e., the semiconductor substrate 10, to the top. The first pillar 15b may be formed to have a maximum linewidth to increase the ON current while minimizing the area required for transistor formation, A common source (not shown) may be formed in the semiconductor substrate 10 below the first pillar 15b.

The second pillar 15a is formed on the first pillar 15b. The second pillar 15a is formed having a narrower linewidth than the first pillar 15b, thereby suppressing the bridge between electrodes, for example, phase-change layers or lower electrodes, in adjacent pillars. A drain (not shown) may be formed in an upper region of the second pillar 15a.

The gate electrode 80a may be formed along an outer wall of the first pillar 15b, The gate electrode 80a may be formed to surround the lower region of the first pillar 15b.

The ohmic contact layer 130 may be formed on the second pillar 15a. In other words, the ohmic contact layer 130 may be formed to cover an upper surface and an edge of a lateral surface, bordering the upper surface, of the second pillar 15a. The purpose of forming the ohmic contact layer 130 in the above-described shape is to increase the contact area between the ohmic contact layer 130 and the pillar 15, and to increase the ON current through contact resistance reduction.

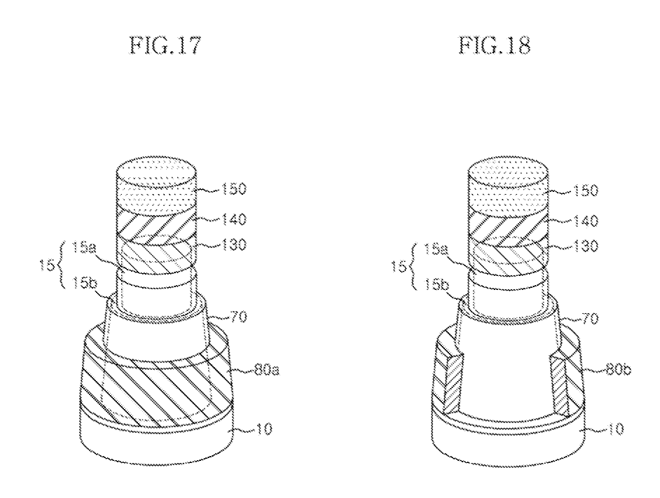

A lower electrode (see 140 of FIG. 17) may be further formed on the ohmic contact layer 130, and a variable resistance layer (see 150 of FIG. 17) may be further formed on the lower electrode.

The reference numerals 100 and 120a indicate a first intercell insulating layer and a second intercell insulating layer, respectively. The reference numerals 110b and 70 indicate a spacer disposed on a lateral surface of the second pillar 15a and a gate insulating layer, respectively.

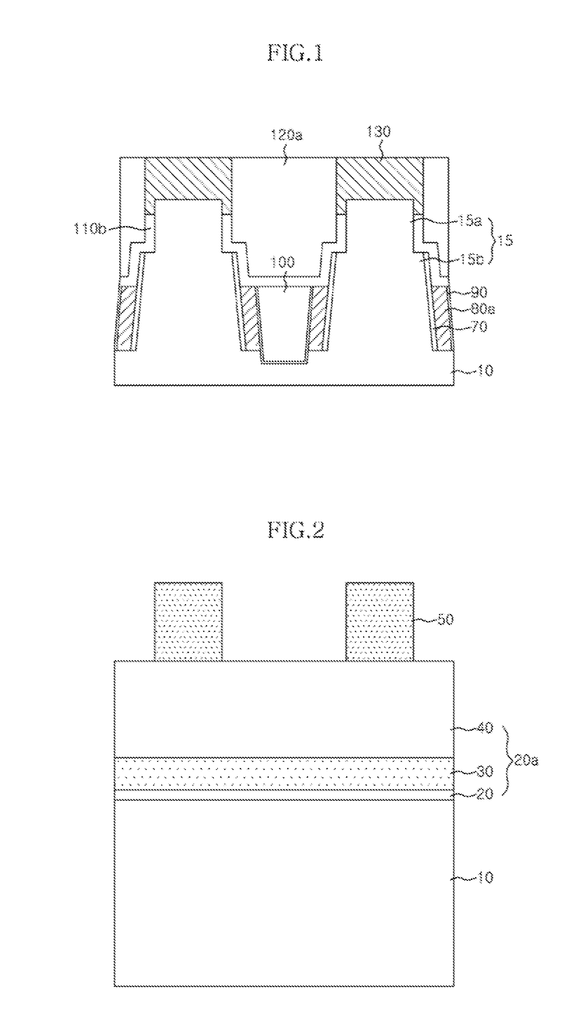

Hereinafter, a method for fabricating a semiconductor apparatus according to an embodiment of the inventive concept will be described with reference to FIGS. 2 to 16.

Referring to FIG. 2, a hard mask pattern 50 for pillar formation is formed on a semiconductor substrate 10.

For example, a protective structure 20a may be formed on the semiconductor substrate 10, and the hard mask pattern 50 may be formed on the protective structure 20a. The protective structure 20a may include a first insulating layer 20, a polysilicon layer 30, and a second insulating layer 40. The first insulating layer 20 may include a silicon oxide layer, and the second insulating layer 40 may include a silicon nitride layer.

The first insulating layer 20 and the polysilicon layer 30 are provided to form a drain contact plug. The first insulating layer 20, an oxide layer, is formed between the semiconductor substrate 10 and the polysilicon layer 30 to prevent damage to the semiconductor substrate 10 which may be caused in a subsequent dip-out process of the polysilicon layer 30 for forming an ohmic contact layer (see 130 of FIG. 16).

The second insulating layer 40 is formed of a silicon nitride layer on the polysilicon layer 30 to prevent the polysilicon layer 30 from being damaged in a subsequent etching process of the semiconductor substrate 10.

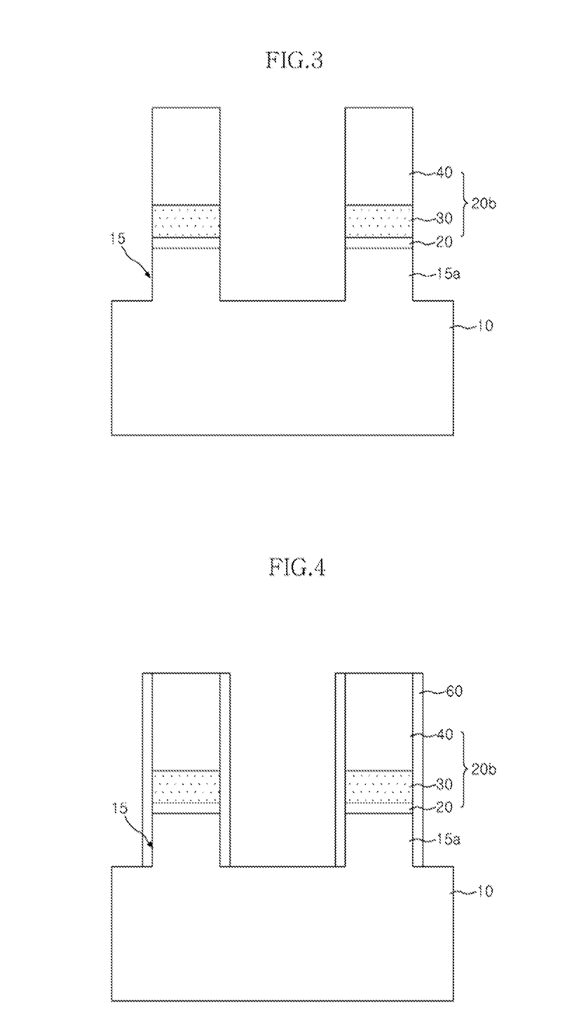

Referring to FIG. 3, the protective structure 20a is etched using the hard mask pattern 50 to form a protective pattern 20b. An upper pillar 15a is formed by first-etching the semiconductor substrate 10 using the hard mask pattern 50 and the protective pattern 20b. The first etching may be performed, for example, through an anisotropic etching method. The hard mask pattern 50 may be removed in the first etching process, or the hard mask pattern 50 may be removed through a general method after the first etching process.

Referring to FIG. 4, a spacer material (not shown) is deposited on the semiconductor substrate in which the upper pillar 15a is formed. The spacer material may be formed of an insulating layer, for example, a silicon oxide layer or a silicon nitride layer. Preferably, the spacer material may be a silicon nitride layer. This is because the first insulating layer 20 is formed of a silicon oxide layer, and it may be damaged in a subsequent removing process of a spacer 60 when the spacer 60 is formed of a silicon oxide layer.

Next, the spacer material is anisotropically etched to form the spacer 60 surrounding lateral surfaces of the upper pillar 15a, the first insulating layer 20, the polysilicon layer 30, and the second insulating layer 40.

Referring to FIG. 5, a lower pillar 15b is formed by second-etching the semiconductor substrate 10 using the protective pattern 20b and the spacer 60 as a mask. As the semiconductor substrate 10 is second-etched using the spacer disposed on an outer wall of the first etched upper pillar 15a, the second etched lower pillar 15b may have a larger linewidth than the upper pillar 15a.

The second etching depth may be deeper than the first etching depth. Thus, since the etch gas must traverse a greater distance in the second etch process, the lower pillar 15b may have a tapered sidewall.

That is, the lower pillar 15b and the upper pillar 15a may form steps due to the thickness of the spacer 60, transfer of the etch medium, or the like.

The purpose of increasing the lower pillar 15b linewidth in the above-described process is to increase current flowing through the pillar 15 even in miniaturization of the semiconductor device by increasing the linewidth of the pillar 15 in a given space, for example, where the pillar 15 is to be formed.

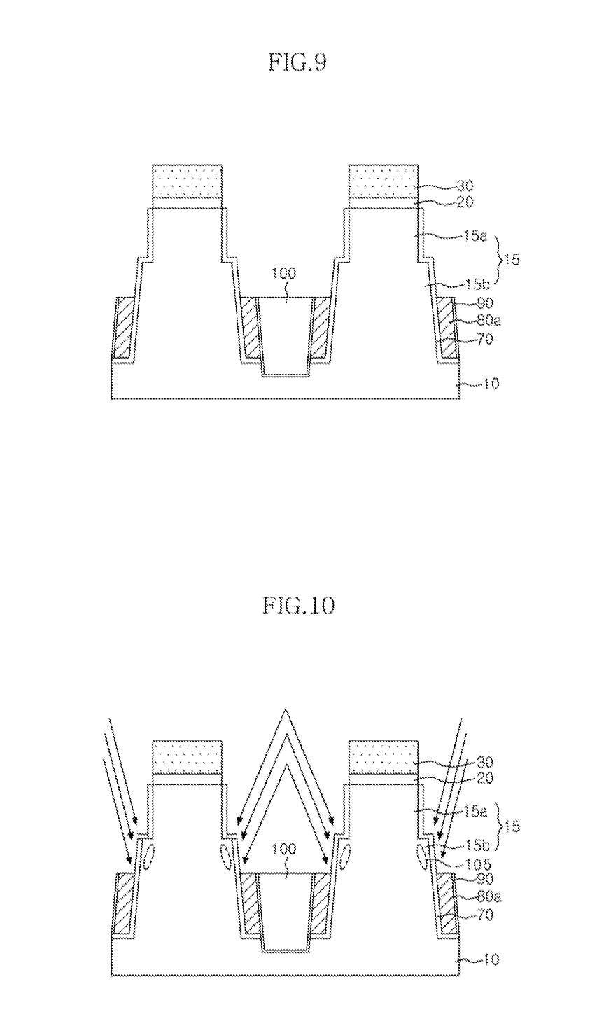

Further, in the embodiment, the lower pillar 15b may have a slope in which the linewidth of the lower pillar 15b is gradually increased towards the bottom. This is because the line width of the pillar 15 is formed to be as large as possible to further increase current flowing in the pillar 15. However, when the lower pillar 15b has a large slope, gate electrodes (see 80a of FIG. 9) of cells may be coupled and cause a short circuit. Therefore, the slope of the lower pillar 15b may be controlled in such a manner that the gate electrodes 80a of the cells are not coupled.

The upper pillar 15a may be formed to have the smaller linewidth than the lower pillar 15b to prevent a bridge between adjacent cells.

Next, a cleaning process for smoothening surface roughness of the semiconductor substrate 10 including the pillar 15 is performed. A high dose annealing may be performed on the pillar 15 in a subsequent process. Since the surface roughness of the pillar 15 is reduced, the temperature in the high dose annealing process may be reduced. Next, the spacer 60 is removed.

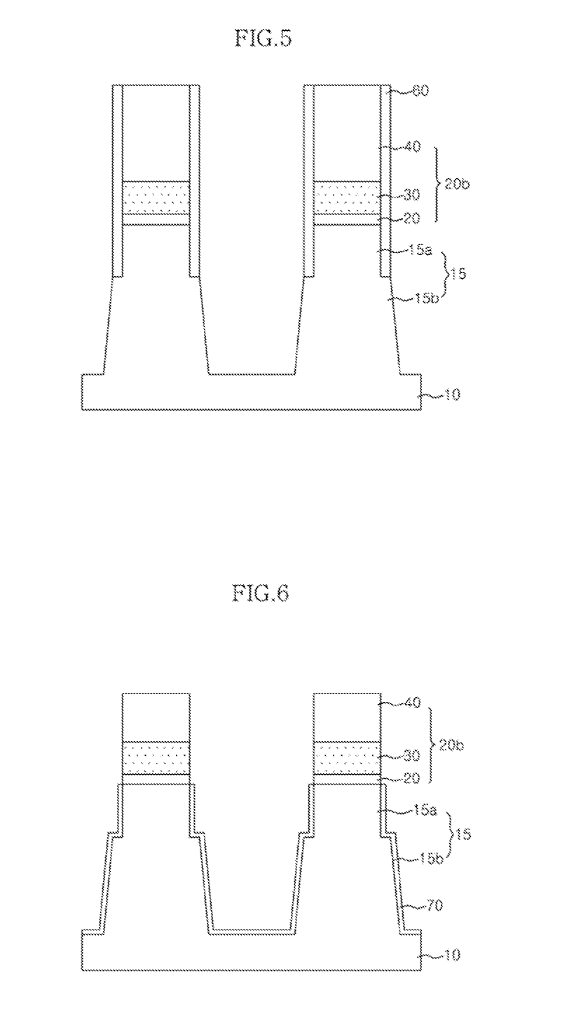

Referring to FIG. 6, a gate insulating layer 70 is formed on a surface of the semiconductor substrate 10 including the pillar 15. For example, the gate insulating layer 70 may include a silicon oxide (SiO₂) layer, a hafnium oxide (HfO₂) layer, a tantalum oxide (Ta₂O₅) layer, or an oxide/nitride/oxide (ONO) layer. In the embodiment, the gate insulating layer 70 may include a silicon oxide layer.

Referring to FIG. 7, a conductive material 80 is formed on the semiconductor substrate 10 including the gate insulating layer 70, and then etched through a spacer formation process. The conductive material 80 may include a titanium nitride (TiN) layer, but the conductive material 80 is not limited thereto.

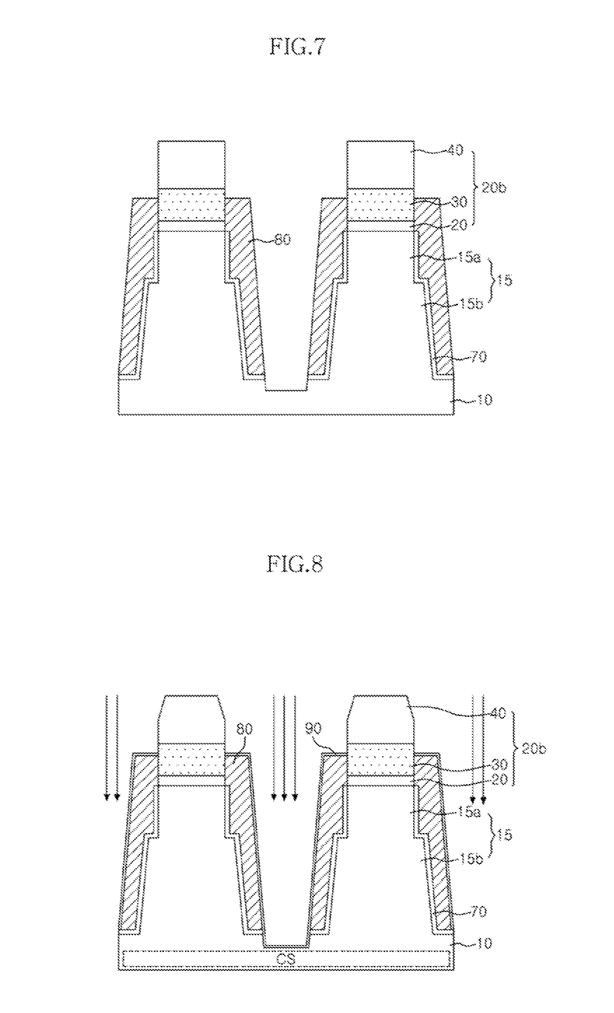

Referring to FIG. 8, a common source region CS is formed by doping the semiconductor substrate 10 below the pillar 15 with impurities, and a capping layer 90 is formed on the semiconductor substrate 10 in which the common source region CS is formed. The common source region CS may be formed by doping the semiconductor substrate 10, and then performing a diffusion process through a heat treatment. The capping layer 90 may include a silicon nitride layer and have a thickness of about 30 Å.

Referring to FIG. 9, an insulating material (not shown) is gap-filled in a space between pillars 15, and is annealed. The insulating material is planarized to have the same height as that of the conductive material 80, and then the insulating material and the conductive material 80 are etched back to form a first intercell insulating layer 100 and the gate electrode 80a insulated by the first intercell insulating layer 100. The etch back process may include a wet etch process or a dry etch process.

The gate electrode 80a formed through the above-described process may entirely overlap a lower region of the lower pillar 15b (see FIG. 17). In other words, the gate electrode 80a may be formed to surround a lower portion of a lowermost step among steps formed in the pillar.

Alternatively, the gate electrode 80b may be formed to overlap the outer circumference of a lower region of the lower pillar 15b in such a manner that a portion of the gate insulating layer 70 is exposed (see FIG. 18).

The purpose of the surface planarization of the insulating material for the first intercell insulating layer 100 in the above-described process is to smoothen the surface of the insulating material roughened in the annealing process of the insulating material. The first intercell insulating layer 100 may be a spin on dielectric (SOD) material, but the first intercell insulating layer 100 is not limited thereto.

Referring to FIG. 10, lightly doped drain (LDD) impurity regions 105 are formed by doping side portions of the pillar 15 with impurities for LDD. The LDD impurity regions 105 may be formed through a tilt ion implantation method as illustrated in FIG. 10.

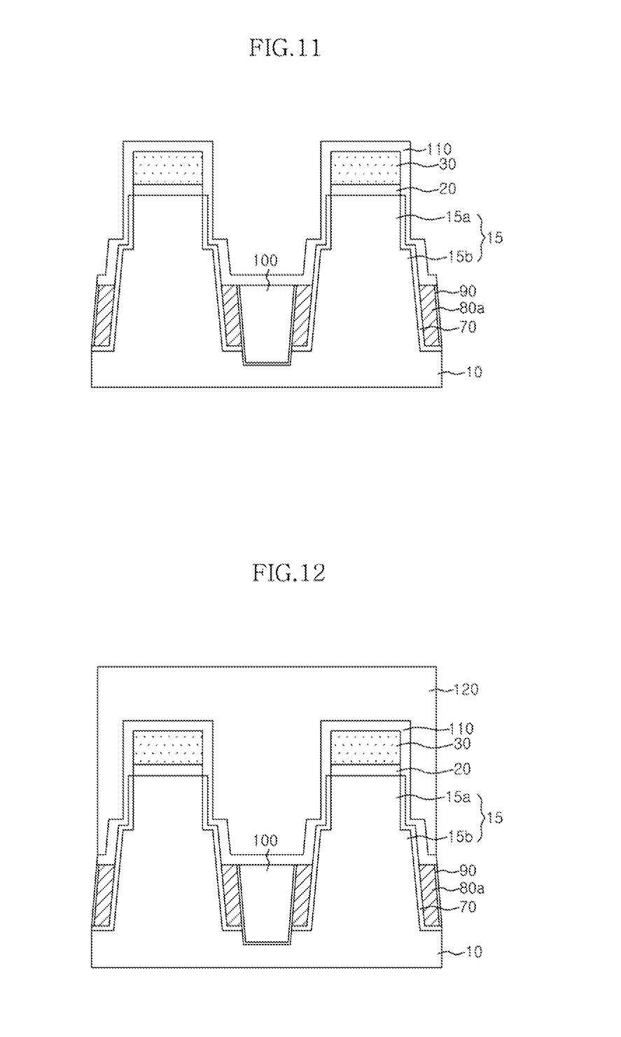

Referring to FIG. 11, a third insulating layer 110 is formed on a surface of the semiconductor substrate 10 in which the gate electrode 80a and the LDD regions 105 are formed. The third insulating layer 110 may be provided for formation of an ohmic contact layer.

Referring to FIG. 12, an insulating material 120 for gap-filling is formed on the third insulating layer 100. The insulating material 120 for gap-filling may be formed to have a thickness sufficient to be gap-filled in the space between the pillars 15. The insulating material 120 for gap-filling may include a material having etch selectivity to the third insulating layer 110, for example, a silicon nitride layer, but the insulating material 120 for gap-filling is not limited thereto.

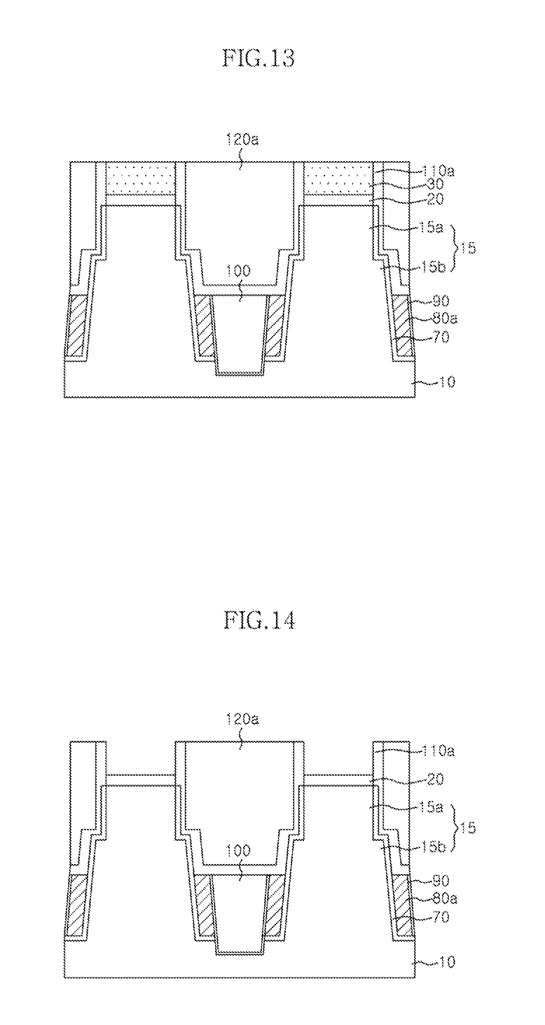

Referring to FIG. 13, a second intercell insulating layer 120a is formed by planarizing the insulating material 120 for gap-filling until a surface of the polysilicon layer 30 constituting the protective pattern 20b is exposed.

Referring to FIG. 14, the polysilicon layer 30 is selectively removed. The polysilicon layer 30 may be removed through a dip-out process using a solution in which only the polysilicon layer 30 is etched.

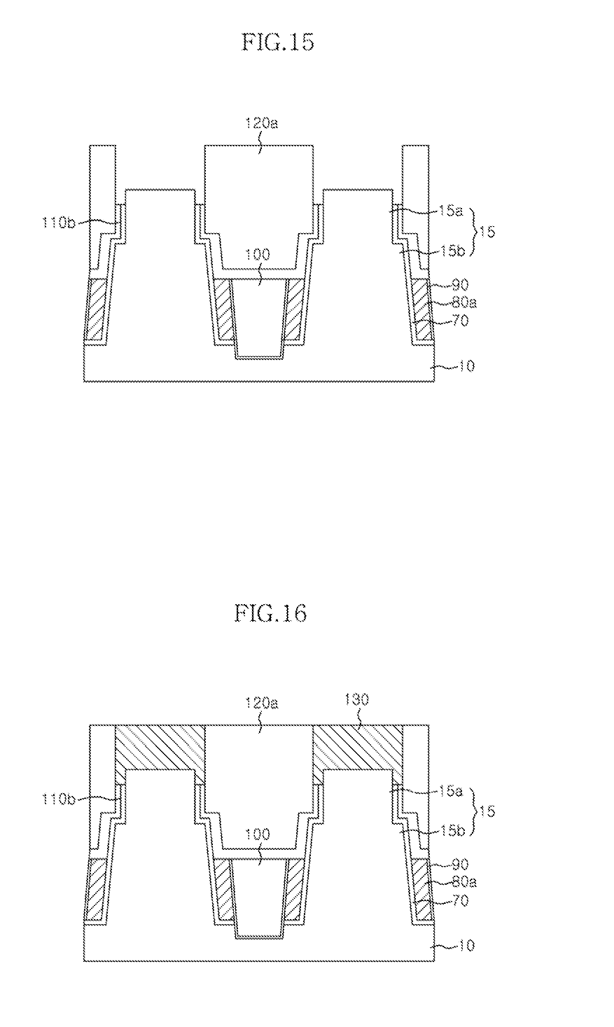

Referring to FIG. 15, the first insulating layer 20 and a portion of the third insulating layer 110a are removed, and a drain region (not shown) is formed by doping the upper pillar 15a exposed through the removal of the first insulating layer 20 and the third insulating layer 110a with impurities. The reference numeral 110b denotes a remaining third insulating layer.

In the above-described process, the first insulating layer 20 and the third insulating layer 110a formed on an upper surface of the pillar 15 may be removed through a dip-out process using a solution for removing the insulating layers. The third insulating layer 110a formed in a lateral surface of the pillar 15 may be recessed through an additional etch method. Through the etch processes, the upper surface and a portion of the lateral surface, bordering the upper surface of the upper pillar, 15a may be exposed.

Referring to FIG. 16, a transition metal layer (not shown) formed on the exposed upper pillar 15a, and a silicide layer 130 having a cap form is formed through a selective reaction between the transition metal layer and the upper pillar 15a.

In other words, the silicide layer 130 may be formed through a series of processes of depositing the transition metal layer in a space formed through the removal of the polysilicon layer 30, the first insulating layer 20, and the third insulating layer 110a, performing a heat treatment for reaction between the transition metal layer and the pillar 15, and removing the remaining transition metal layer after the heat treatment.

In the formation process of the silicide layer, the transition metal layer may be deposited through a sputtering method. As an edge portion of the upper pillar 15a may be changed in a round shape by the impurities in the preceding process of doping the upper pillar 15a, the silicide formation material may be easily deposited through the sputtering method.

The silicide layer 13 may be formed to surround the upper surface and a portion of the lateral surface, bordering the upper surface, of the pillar 15 exposed in the preceding process.

As in the embodiment, when the upper pillar 15a is formed in a stepped shape having a smaller linewidth than the lower pillar 15b, the area of the silicide layer 130 which is in contact with the upper pillar 15a may be reduced. Thus, the contact resistance between the silicide layer 130 and the pillar 15 may be increased, and the ON current may be reduced. Therefore, in the embodiment, the area of the silicide layer 130 which is in contact with the upper pillar 15a is substantially increased by forming the silicide layer 130 to surround the upper surface and the portion of the lateral surface bordering to the upper surface, of the pillar 15. Thus, the contact resistance may be reduced, and the ON current may be increased.

Another method embodiment of forming the silicide layer will be described with reference to FIGS. 15 and 16.

Referring to FIG. 15, a drain (not shown) is formed by doping the upper pillar 15a, which is surrounded with the first insulating layer 20 and the third insulating layer 110a by removing the polysilicon layer 30 in the preceding process of FIG. 14, with impurities. The first insulating layer 20 and a portion of the third insulating layer 110a are removed.

In the above-described process, as the semiconductor substrate, that is, the pillar 15 is in contact with the first and third insulating layers 20 and 110a formed of a silicon oxide layer material, the shape of the pillar 15 may be changed.

Referring to FIG. 16, a silicide layer 130 is formed on the upper pillar 15a. The silicide layer 130 may be formed through a series of processes of depositing a transition metal layer (not shown) in a space formed through the removal of the polysilicon layer 30, the first insulating layer 20, and a portion of the third insulating layer 110a, performing a heat treatment for a reaction between the transition metal layer and the upper pillar 15, and removing the remaining transition metal layer after the heat treatment. At this time, the transition metal layer may be deposited through a chemical vapor deposition (CVD) method since the shape of the pillar 15 is not changed.

Referring to FIGS. 17 and 18, a lower electrode 140 may be formed on the silicide layer 130. A variable resistance layer 150 may be formed on the lower electrode 140, and an upper electrode (not shown) may be formed on the variable resistance layer 150. The lower electrode 140, the variable resistance layer 150, and the upper electrode are sequentially formed on the silicide layer 130 to complete the variable resistive memory device.

As described above, the pillar in the embodiment may be provided in a stepwise shape in such a manner that the linewidth of the lower pillar is larger than that of the upper pillar. The lower pillar may allow the current flowing through the lower pillar to be increased. At the same time, the upper pillar is formed to have the smaller linewidth than the lower pillar to prevent a bridge between adjacent cells from occurring. Further, even when the upper pillar is formed to have a small linewidth, the silicide layer is formed on the upper surface and a portion of the lateral surface, bordering the upper surface, of the pillar is formed to increase its contact area with the upper pillar, and the ON current is increased.

Although a pillar having a step is formed by etching the semiconductor substrate in the embodiment, the pillar formation method is not limited thereto, and a method of forming a pillar including forming an epitaxial layer on the semiconductor substrate and etching the epitaxial layer may be also employed.

The above embodiment of the present invention is illustrative and not limitative, Various alternatives and equivalents are possible. The invention is not limited by the embodiments described herein. Nor is the invention limited to any specific type of semiconductor device. Other additions, subtractions, or modifications are obvious in view of the present disclosure and are intended to fall within the scope of the appended claims.

What is claimed is:

1. A semiconductor apparatus comprising:
a semiconductor substrate; and
a plurality of pillars formed in the semiconductor substrate,
wherein each of the plurality of pillars includes a first pillar, and a second pillar formed on the first pillar, wherein the second pillar has a smaller linewidth than the first pillar.

2. The semiconductor apparatus of claim further comprising:
a gate electrode disposed on an outer wall of the first pillar.

3. The semiconductor apparatus of claim 2, further comprising:
an intercell insulating layer disposed between gate electrodes surrounding adjacent pillars among the plurality of pillars.

4. The semiconductor apparatus of claim 1, wherein the first pillar has a linewidth increasing as a level of the first pillar is lowered.

5. The semiconductor apparatus of claim 1, further comprising:
an ohmic contract layer formed to surround an upper surface and an edge of a lateral surface, bordering the upper surface, of the second pillar.

6. A method for fabricating a semiconductor apparatus, the method comprising:
forming an upper pillar by first-etching a semiconductor substrate;
forming a spacer on an outer wall of the upper pillar; and
forming a lower pillar by second-etching the semiconductor substrate using the upper pillar and the spacer.

7. The method of claim 6, wherein a linewidth of the lower pillar at least includes a linewidth of the upper pillar and a linewidth of the spacer.

8. The method of claim 7, further comprising, after the forming of the lower pillar:
forming a gate electrode to overlap a lower region of the lower pillar.

9. The method of claim 8, wherein the forming of the gate electrode includes:
forming a conductive material layer on a surface of the pillar;
burying an insulating material layer in a space between pillars; and
etching back the conductive material layer and the insulating material layer.

10. The method of claim 7, further comprising, after the forming of the lower pillar:
forming a source in the lower pillar and the semiconductor substrate; and
forming a drain in an upper portion of the upper pillar.

11. The method of claim 10, further comprising, after the forming of the drain:
forming an ohmic contact layer on an upper surface and an edge of a lateral surface, bordering the upper surface, of the upper pillar;
forming a lower electrode on the ohmic contact layer; and
forming a variable resistance layer on the lower electrode.

12. A variable resistive memory device comprising:
a semiconductor substrate;
pillars formed in the semiconductor substrate, each of the pillars having two or more layers, wherein a first layer has a larger linewidth than a second layer formed on the first layer;
a gate electrode formed to surround a lower region of each of the pillars;
a source formed in the semiconductor substrate below each of the pillars; and
a drain formed in an upper region of each of the pillars; and
a variable resistance layer formed to be electrically coupled to the drain.

13. The variable resistive memory device of claim 12, wherein each of the pillars has a linewidth that increases in a direction going towards the semiconductor substrate.

14. The variable resistive memory device of claim 12, wherein the each of the pillars includes:
an upper pillar formed at the second layer; and
a lower pillar formed at the first layer and having a larger linewidth than the upper pillar.

15. The variable resistive memory device of claim 14, wherein the upper pillar has a sidewall substantially perpendicular to the semiconductor substrate, and
the lower pillar has a tapered sidewall from the semiconductor substrate to a top.

16. The variable resistive memory device of claim 12, wherein the gate electrode surrounds a lower region of a lowermost layer of the two or more layers formed in the pillar.

17. The variable resistive memory device of claim 12, further comprising:
a gate insulating layer formed between the gate electrode and the pillar.

18. The variable resistive memory device of claim 12, wherein the source is formed in the semiconductor substrate between the pillars to form a common source.

19. The variable resistive memory device of claim 1, further comprising:
an ohmic contact layer formed between the drain and the variable resistance layer and on an upper surface and an edge of a lateral surface, bordering the upper surface, of each of the pillars.

20. The variable resistive memory device of claim 16, further comprising:
a lower electrode formed on the ohmic contact layer.
